(19) United States
(12) Patent Application Publication
(10) Pub. No.: US 2018/0206299 A1
(43) Pub. Date: Jul. 19, 2018

(54) MICRO LED DISPLAY DEVICE

(71) Applicant: SHENZHEN CHINA STAR OPTOELECTRONICS TECHNOLOGY CO., LTD., Guangdong (CN)

(72) Inventor: Lixuan CHEN, Shenzhen City (CN)

(21) Appl. No.: 15/116,215

(22) PCT Filed: Jun. 29, 2016
(86) PCT No.: PCT/CN2016/087636

§ 371 Date: Aug. 3, 2016

(30) Foreign Application Priority Data
Jun. 20, 2016 (CN) 201610448851.1

(51) Int. Cl. H05B 33/02; H01L 51/52; H01L 27/32; H01L 33/52

(52) U.S. Cl. CPC H05B 33/02; H01L 33/52; H01L 27/32; H01L 51/5275

(57) ABSTRACT

The invention provides a micro LED display device, by using a white micro LED (211) with a red filter layer (212), or a green micro LED with a red photoluminescent layer, or a blue micro LED with a red photoluminescent layer to display a red sub-pixel (21), without manufacturing red micro LED so as to reduce production difficulty of micro LED display device. Also, by adding a filter layer on the micro LEDs, the color purity of the micro LED display device is enhanced, the gamut of the micro LED display device is expanded and the display quality of the micro LED display device is improved.

### BACKGROUND OF THE INVENTION

### 1. Field of the Invention

The present invention relates to the field of display, and in particular to a micro light-emitting diode (micro LED) display device.

### 2. The Related Arts

The panel display device, due to the advantages of high display quality, low power-consumption, thin size and wide application, is widely used in mobile phones, TV, PDA, digital camera, notebook PC, desktop PC, and so on, and becomes the mainstream technology.

The micro light-emitting diode (micro LED, μLED) display device is a display device which utilizes high density micro-scaled LED array integrated on a substrate as display pixels to achieve image display. Similar to a larger-scaled outdoor LED display, each pixel is addressable and individually driven to emit light, and can be viewed as a reduce-sized outdoor LED display by reducing the inter-pixel distance from cm scale to mm scale. Micro LED display device and the organic light-emitting diode (OLED) are both self-luminous, but the micro LED shows the advantages of higher material stability, longer lifespan and no image imprinting as compared to the OLED, and is considered as the major competing technology for OLED display device.

The micro transfer printing (MTP) is the mainstream technology to manufacture micro LED display device. Specifically, first, the micro LED element is grown on the sapphire-based substrate; a laser lift-off (LLO) technology is used to separate the micro LED bare chip from the sapphire-based substrate, and then a patterned polydimethylsiloxane (PDMS) transfer stamp is used to adsorb to the micro LED bare chip off from the sapphire-based substrate; the PDMS transfer stamp is aligned with the receiving substrate for positioning; and then the micro LED bare chip adsorbed by the PDMS transfer stamp is attached to the pre-set position on the receiving substrate; and then the PDMS transfer stamp is peeled off to accomplish micro LED bare chip transfer to further manufacture the micro LED display device.

At present, the structure for blue micro LED and green micro LED is mainly a horizontal structure of sapphire substrate, and the structure for red micro LED is mainly a vertical structure of GaAs substrate. Because the red micro LED is different from the blue micro LED or green micro LED grown on the sapphire substrate, it is difficult to employ the known flip chip technology to prepare the red micro LED with positive and negative electrodes at the same side.

Moreover, due to narrow gamut and lower display quality for micro LED display device using only the micro LED as basic display unit, the expansion of gamut is necessary to improve the display quality of the micro LED display device.

### SUMMARY OF THE INVENTION

The object of the present invention is to provide a micro LED display device, able to reduce production difficulty of micro LED display device, expand gamut of micro LED display device and improve the display quality of micro LED display device.

To achieve the above object, the present invention provides a micro LED display device, which comprises: a substrate, and a plurality of display pixels disposed on the substrate and arranged in an array; each display pixel at least comprising a red sub-pixel; the red sub-pixel comprising: at least a white micro LED disposed on the substrate, and a red filter layer disposed on the white micro LED.

Each display pixel further comprises a green sub-pixel, and a blue sub-pixel; the green sub-pixel comprises: at least a white micro LED disposed on the substrate, and a green filter layer disposed on the white micro LED; the blue sub-pixel comprises: at least a white micro LED disposed on the substrate, and a blue filter layer disposed on the white micro LED.

Each display pixel further comprises a green sub-pixel, and a blue sub-pixel; the green sub-pixel comprises: at least a white micro LED disposed on the substrate, and a green filter layer disposed on the white micro LED; the blue sub-pixel comprises: at least a blue micro LED disposed on the substrate.

Each display pixel further comprises a green sub-pixel, and a blue sub-pixel; the green sub-pixel comprises: at least a green micro LED disposed on the substrate; the blue sub-pixel comprises: at least a white micro LED disposed on the substrate, and a blue filter layer disposed on the white micro LED.

Each display pixel further comprises a green sub-pixel, and a blue sub-pixel; the green sub-pixel comprises: at least a green micro LED disposed on the substrate; the blue sub-pixel comprises: at least a blue micro LED disposed on the substrate.

The red filter layer comprises a red photoluminescent material.

The green filter layer comprises a green photoluminescent material.

The blue filter layer comprises a blue photoluminescent material.

The present invention also provides a micro LED display device, which comprises: a substrate, and a plurality of display pixels disposed on the substrate and arranged in an array; each display pixel at least comprising a red sub-pixel; the red sub-pixel comprising: at least a blue micro LED or a green micro LED disposed on the substrate, and a red photoluminescent layer disposed on the blue micro LED or the green micro LED.

Each display pixel further comprises a green sub-pixel, and a blue sub-pixel; the green sub-pixel comprises: at least a green micro LED disposed on the substrate; the blue sub-pixel comprises: at least a blue micro LED disposed on the substrate.

The present invention also provides a micro LED display device, which comprises: a substrate, and a plurality of display pixels disposed on the substrate and arranged in an array; each display pixel at least comprising a red sub-pixel; the red sub-pixel comprising: at least a white micro LED disposed on the substrate, and a red filter layer disposed on the white micro LED; wherein each display pixel further comprising a green sub-pixel, and a blue sub-pixel; the green sub-pixel comprising: at least a white micro LED disposed on the substrate, and a green filter layer disposed on the white micro LED; the blue sub-pixel comprising: at least a white micro LED disposed on the substrate, and a blue filter layer disposed on the white micro LED; wherein the red filter layer comprising a red photoluminescent material.

Compared to the known techniques, the present invention provides the following advantages: the present invention provides a micro LED display device, by using a white micro LED with a red filter layer, or a green micro LED with a red photoluminescent layer, or a blue micro LED with a red photoluminescent layer to display a red sub-pixel, without manufacturing red micro LED so as to reduce production difficulty of micro LED display device. Also, by adding a filter layer on the micro LEDs, the color purity of the micro LED display device is enhanced, the gamut of the micro LED display device is expanded and the display quality of the micro LED display device is improved.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the structure of the micro LED display device provided by a first embodiment of the present invention;

FIG. 2 is a schematic view showing the structure of the micro LED display device provided by a second embodiment of the present invention;

FIG. 3 is a schematic view showing the structure of the micro LED display device provided by a third embodiment of the present invention;

FIG. 4 is a schematic view showing the structure of the micro LED display device provided by a forth embodiment of the present invention;

FIG. 5 is a schematic view showing the structure of the micro LED display device provided by a fifth embodiment of the present invention;

FIG. 6 is a schematic view showing the structure of the micro LED display device provided by a sixth embodiment of the present invention.

### DETAILED DESCRIPTION OF THE PREFERRED EMBODIMENTS

To further explain the technical means and effect of the present invention, the following refers to embodiments and drawings for detailed description.

The present invention provides a micro LED display device, by using the non-red micro LEDs, such as, white, green or blue micro LEDs, and an auxiliary layer, such as, red filtering layer or red photoluminescent layer to display a red sub-pixel to avoid manufacturing red micro LEDs in producing the micro LED display device and reduce the production difficulty of micro LED display device.

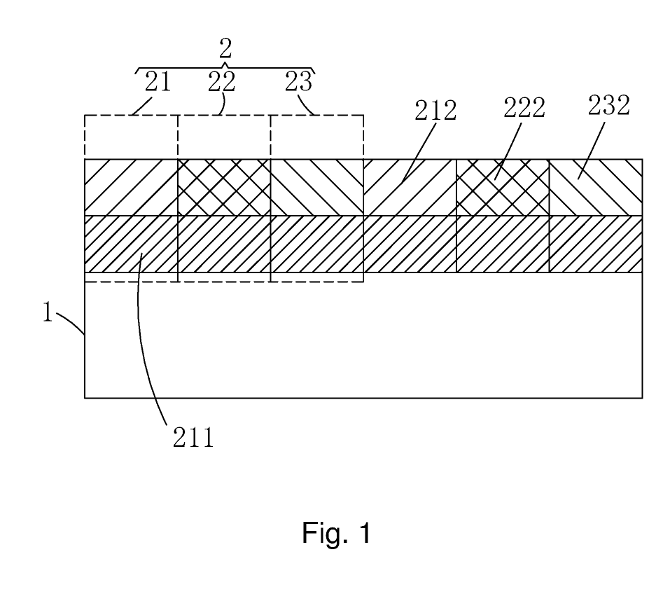

Refer to FIGS. 1-4. In the first to fourth embodiments of the present invention, the micro LED display device uses the white micro LEDs with a red filter layer to display the red sub-pixel, and specifically comprises: a substrate 1, and a plurality of display pixels 2 disposed on the substrate 1 and arranged in an array; each display pixel 2 at least comprising a red sub-pixel 21; the red sub-pixel comprising 21: at least a white micro LED 211 disposed on the substrate 1, and a red filter layer 212 disposed on the white micro LED 211.

Moreover, each display pixel 2 further comprises a green sub-pixel 22, and a blue sub-pixel 23. In other words, each display pixel 2 comprises a red sub-pixel 21, a green sub-pixel 22 and a blue sub-pixel 23. With light emitted by the red sub-pixel 21, green sub-pixel 22 and blue sub-pixel 23, a color image can be displayed.

Specifically, the substrate 1 is also disposed with thin film transistor (TFT) array for driving the micro LEDs to emit light. Optionally, the TFT array is silicon-based TFT array, such as, amorphous silicon (a-Si) TFT or low-temperature polysilicon (LTPS) TFT array, or oxide TFT array, such as, indium gallium zinc oxide (IGZO) TFT array.

Moreover, refer to FIG. 1. In the first embodiment of the present invention, the green sub-pixel 22 comprises: at least a white micro LED 211 disposed on the substrate 1, and a green filter layer 222 disposed on the white micro LED 211; and the blue sub-pixel 23 comprises: at least a white micro LED 211 disposed on the substrate 1, and a blue filter layer 232 disposed on the white micro LED 211. In other words, in the first embodiment of the present invention, the red, green and blue sub-pixels 21, 22, 23 are all realized by white micro LED 211 with a filter layer. Compared to the micro LED display device only uses color micro LEDs to realize corresponding color sub-pixel respectively, the first embodiment provides a broader gamut and better display quality.

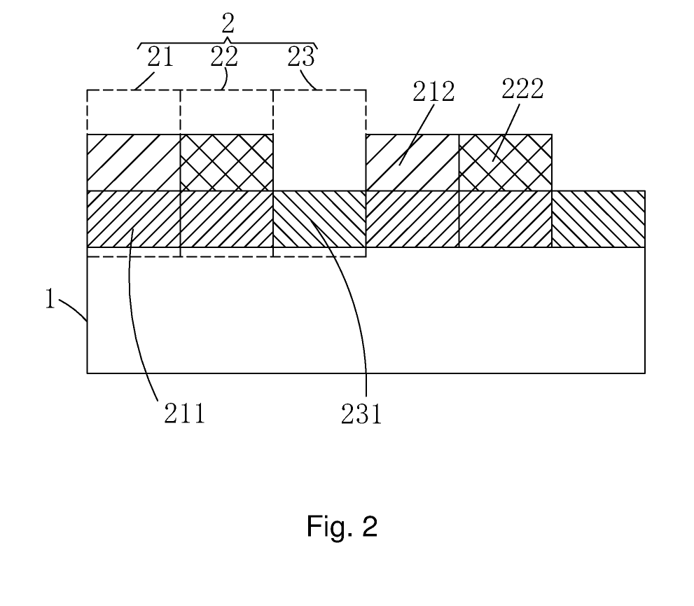

Refer to FIG. 2. The second embodiment differ from the first embodiment in that, the blue sub-pixel 23 comprises: at least a blue micro LED 231 disposed on the substrate 1. In other words, in the second embodiment of the present invention, the blue sub-pixel 23 is realized by blue micro LED 231 without a filter layer. The remaining is the same as the first embodiment, and the detailed description is not repeated.

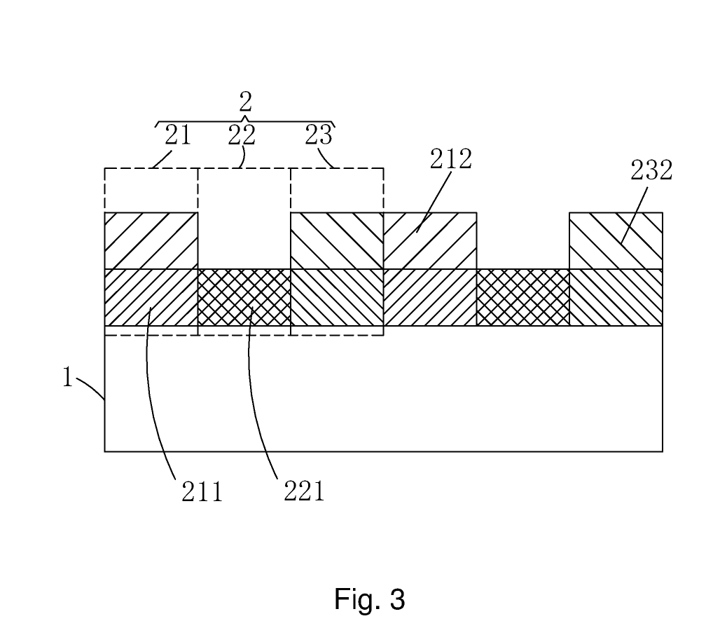

Refer to FIG. 3. The third embodiment differ from the first embodiment in that, the green sub-pixel 22 comprises: at least a green micro LED 221 disposed on the substrate 1. In other words, in the third embodiment of the present invention, the green sub-pixel 22 is realized by green micro LED 221 without a filter layer. The remaining is the same as the first embodiment, and the detailed description is not repeated.

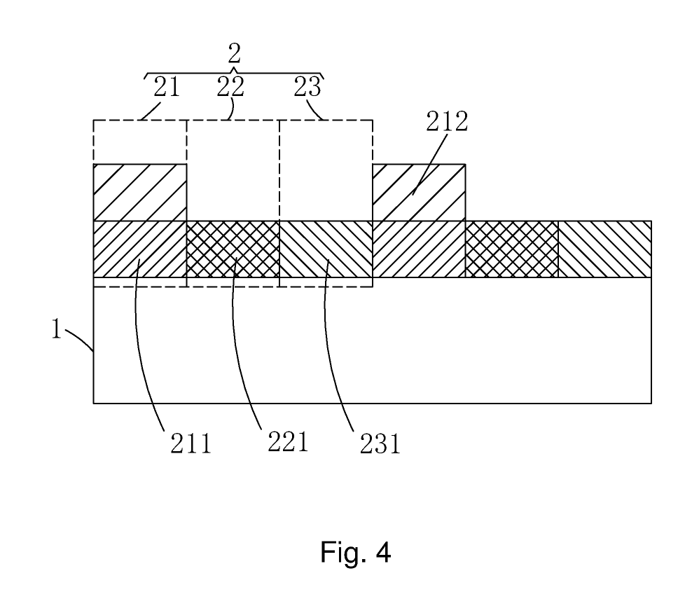

Refer to FIG. 4. The fourth embodiment differ from the first embodiment in that, the green sub-pixel 22 comprises: at least a green micro LED 221 disposed on the substrate 1; and the blue sub-pixel 23 comprises: at least a blue micro LED 231 disposed on the substrate 1. In other words, in the fourth embodiment of the present invention, the green sub-pixel 22 and the blue sub-pixel 23 are realized respectively by green micro LED 221 and blue micro LED 231 without a filter layer. The remaining is the same as the first embodiment, and the detailed description is not repeated.

It should be noted that in the first to fourth embodiments of the present invention, each color filter layer can comprises a quantum dot (QD) photoluminescent material to further expand the gamut of the micro LED display device. The light color of the photoluminescent material corresponds to the color of the filter layer, for example, the red filter layer 212 comprises a red photoluminescent material; the green filter layer 222 comprises a green photoluminescent material; and the blue filter layer 232 comprises a blue photoluminescent material.

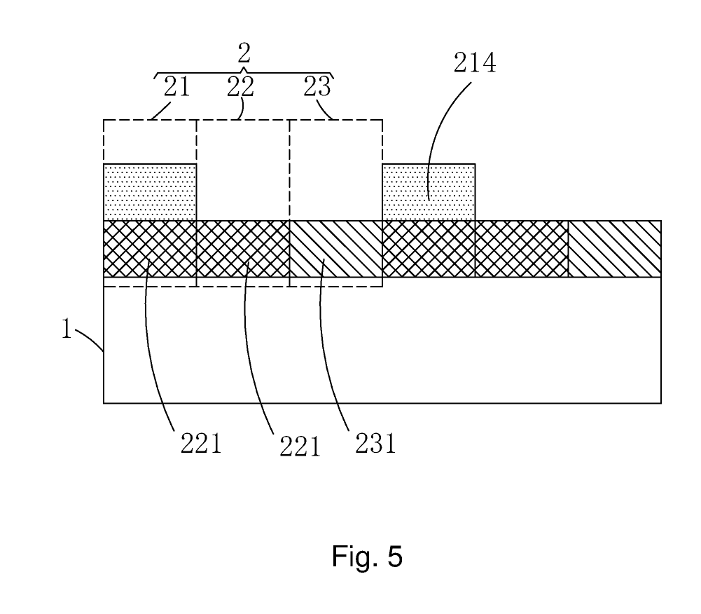

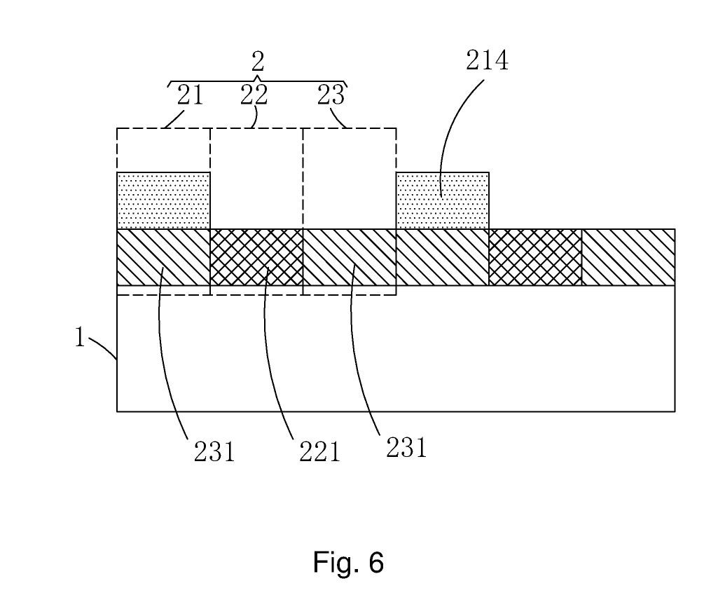

Refer to FIGS. 5 and 6. In the fifth and sixth embodiments of the present invention, the micro LED display device uses blue or green micro LEDs with a red photoluminescent layer to realize the red sub-pixel, and specifically comprises: a substrate 1, and a plurality of display pixels 2 disposed on the substrate 1 and arranged in an array; each display pixel 2 at least comprising a red sub-pixel 21; the red sub-pixel 21 comprising: at least a blue micro LED 231 or a green micro LED 221 disposed on the substrate 1, and a red photoluminescent layer 214 disposed on the blue micro LED 231 or the green micro LED 221.

Moreover, each display pixel 2 further comprises a green sub-pixel 22, and a blue sub-pixel 23; the green sub-pixel 22 comprises: at least a green micro LED 221 disposed on the substrate 1; the blue sub-pixel 23 comprises: at least a blue micro LED 231 disposed on the substrate 1.

Specifically, the substrate 1 is also disposed with thin film transistor (TFT) array for driving the micro LEDs to emit light. Optionally, the TFT array is silicon-based TFT array, such as, amorphous silicon (a-Si) TFT or low-temperature polysilicon (LTPS) TFT array, or oxide TFT array, such as, indium gallium zinc oxide (IGZO) TFT array.

Specifically, refer to FIG. 5. The fifth embodiment of the present invention uses the green micro LED 221 with a red photoluminescent layer 214 to realize the red sub-pixel 21. Correspondingly, refer to FIG. 6. The sixth embodiment of the present invention uses the green micro LED 231 with a red photoluminescent layer 214 to realize the red sub-pixel 21.

It should be noted that the aforementioned white micro LED 211, green LED 221 and blue LED 231 can all be produced by micro transfer printing (MTP). Specifically, the structure comprises a sapphire substrate, an N-type semiconductor layer disposed on the sapphire substrate, a multiple quantum well layer disposed on the N-type semiconductor layer, P-type semiconductor layer disposed on the multiple quantum well layer, a contact layer disposed on the P-type semiconductor layer, a current diffusion layer disposed on the contact layer, a first electrode disposed on the current diffusion layer, and an insulating layer surrounding the first electrode, and a second electrode disposed on the N-type semiconductor layer extending beyond the light-emitting area, i.e., the first electrode and the second electrode being at the same plane. The micro LEDs can be transferred onto the receiving substrate by MTP, wherein the first electrode is made of an alloy of nickel and gold, or alloy of palladium and gold; the N-type semiconductor layer and the P-type semiconductor layer can be made of gallium nitride (GaN), indium gallium nitride (InGaN), zinc selenide (ZnSe), gallium phosphide (GaP) or aluminum indium gallium phosphide (AlGaInP).

In summary, the present invention provides a micro LED display device, by using a white micro LED with a red filter layer, or a green micro LED with a red photoluminescent layer, or a blue micro LED with a red photoluminescent layer to display a red sub-pixel, without manufacturing red micro LED so as to reduce production difficulty of micro LED display device. Also, by adding a filter layer on the micro LEDs, the color purity of the micro LED display device is enhanced, the gamut of the micro LED display device is expanded and the display quality of the micro LED display device is improved.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A micro light-emitting diode (LED) display device, which comprises: a substrate, and a plurality of display pixels disposed on the substrate and arranged in an array;
each display pixel at least comprising a red sub-pixel;
the red sub-pixel comprising: at least a white micro LED disposed on the substrate, and a red filter layer disposed on the white micro LED.

2. The micro LED display device as claimed in claim 1, wherein each display pixel further comprises a green sub-pixel, and a blue sub-pixel;
the green sub-pixel comprises: at least a white micro LED disposed on the substrate, and a green filter layer disposed on the white micro LED;
the blue sub-pixel comprises: at least a white micro LED disposed on the substrate, and a blue filter layer disposed on the white micro LED.

3. The micro LED display device as claimed in claim 1, wherein each display pixel further comprises a green sub-pixel, and a blue sub-pixel;
the green sub-pixel comprises: at least a white micro LED disposed on the substrate, and a green filter layer disposed on the white micro LED;
the blue sub-pixel comprises: at least a blue micro LED disposed on the substrate.

4. The micro LED display device as claimed in claim 1, wherein each display pixel further comprises a green sub-pixel, and a blue sub-pixel;
the green sub-pixel comprises: at least a green micro LED disposed on the substrate;
the blue sub-pixel comprises: at least a white micro LED disposed on the substrate, and a blue filter layer disposed on the white micro LED.

5. The micro LED display device as claimed in claim 1, wherein each display pixel further comprises a green sub-pixel, and a blue sub-pixel;
the green sub-pixel comprises: at least a green micro LED disposed on the substrate;
the blue sub-pixel comprises: at least a blue micro LED disposed on the substrate.

6. The micro LED display device as claimed in claim 1, wherein the red filter layer comprises a red photoluminescent material.

7. The micro LED display device as claimed in claim 2, wherein the substrate is a silicon-based thin film transistor (TFT) array or an oxide TFT array, and the blue filter layer comprises a blue photoluminescent material.

8. The micro LED display device as claimed in claim 2, wherein the green filter layer comprises a green photoluminescent material.

9. A micro LED display device, which comprises: a substrate, and a plurality of display pixels disposed on the substrate and arranged in an array;
each display pixel at least comprising a red sub-pixel;
the red sub-pixel comprising: at least a blue micro LED or a green micro LED disposed on the substrate, and a red photoluminescent layer disposed on the blue micro LED or the green micro LED.

10. The micro LED display device as claimed in claim 9, wherein each display pixel further comprises a green sub-pixel, and a blue sub-pixel;
the green sub-pixel comprises: at least a green micro LED disposed on the substrate;
the blue sub-pixel comprises: at least a blue micro LED disposed on the substrate.

11. A micro LED display device, which comprises: a substrate, and a plurality of display pixels disposed on the substrate and arranged in an array;
each display pixel at least comprising a red sub-pixel;
the red sub-pixel comprising: at least a white micro LED disposed on the substrate, and a red filter layer disposed on the white micro LED;
wherein each display pixel further comprising a green sub-pixel, and a blue sub-pixel;
the green sub-pixel comprising: at least a white micro LED disposed on the substrate, and a green filter layer disposed on the white micro LED;
the blue sub-pixel comprising: at least a white micro LED disposed on the substrate, and a blue filter layer disposed on the white micro LED;
wherein the red filter layer comprising a red photoluminescent material.

12. The micro LED display device as claimed in claim 11, wherein the substrate is a silicon-based thin film transistor (TFT) array or an oxide TFT array, and the blue filter layer comprises a blue photoluminescent material.

13. The micro LED display device as claimed in claim 11, wherein the green filter layer comprises a green photoluminescent material.
